(19) United States
(12) Patent Application Publication
(10) Pub. No.: US 2023/0069862 A1
(43) Pub. Date: Mar. 9, 2023

(54) METHOD FOR MANUFACTURING AN INTEGRATED CIRCUIT

(71) Applicant: COMMISSARIAT À L’ENERGIE ATOMIQUE ET AUX ENERGIES ALTERNATIVES, PARIS (FR)

(72) Inventors: Thibaud FACHE, GRENOBLE CEDEX 09 (FR); Yves MORAND, GRENOBLE CEDEX 09 (FR)

(21) Appl. No.: 17/901,346

(22) Filed: Sep. 1, 2022

(30) Foreign Application Priority Data
Sep. 2, 2021 (FR) 2109178

(51) Int. Cl. H01L 21/762; H01L 21/768

(52) U.S. Cl. CPC H01L 21/76286; H01L 21/76802

(57) ABSTRACT

A method for manufacturing an integrated circuit, includes providing a stack including a substrate and a dielectric layer disposed on the substrate, the substrate being formed from a semiconductor material having a resistivity greater than or equal to 500 Ω.cm, etching trenches extending through the dielectric layer and opening onto the substrate; etching the substrate isotropically and selectively with respect to the dielectric layer to form first cavities in the substrate; depositing a mobile electrical charge-trapping layer on the walls of the first cavities and on the side walls of the trenches so as to fill in the trenches in the dielectric layer, thus closing the first cavities in the substrate; and forming passive components vertically with respect to the first cavities.

### CROSS-REFERENCE TO RELATED APPLICATIONS

This application claims priority to French Patent Application No. 2109178, filed Sep. 2, 2021, the entire content of which is incorporated herein by reference in its entirety.

### FIELD

The present invention relates to the semiconductor substrates used to manufacture integrated circuits, and more particularly radiofrequency (RF) circuits.

### BACKGROUND

Different types of substrate can be used to manufacture integrated circuits. The substrate is generally chosen according to the type of circuit to be manufactured: radiofrequency (RF) circuit, MOS transistor-based logic circuits with, image sensors . . .

Among the substrates of interest, mention can be made of the SOI (for “Silicon On Insulator”) multilayer structure. The SOI multilayer structure successively comprises a support layer made of silicon, an electrically insulating layer, generally a so-called buried oxide layer (or BOX layer), and a thin film made of monocrystalline silicon, also called the active layer. The active layer is named as such because it is intended to receive active components, typically MOS transistors (acronym for “Metal Oxide Semiconductor”). The conduction channel of the MOS transistors is formed in the active layer. The structure SOI offers in particular the possibility of manufacturing fully depleted (or FDSOI, for “Fully Depleted SOI”) or partially depleted (or PDSOI, for “Partially Depleted SOI”) transistors.

FIG. 1 shows another multilayer structure 10, derived from the SOI structure and commonly used to manufacture RF integrated circuits, such as the RF signal transmission-reception modules integrated into portable telephones (so-called “front-end” modules).

This multilayer structure 10, called “TR-SOI”, successively comprises a support layer 11 made of high resistivity silicon, a trap-rich layer 12, a buried oxide layer 13 and an active layer 14 made of monocrystalline silicon. The trap-rich layer 12 prevents the parasitic conduction phenomenon at the interface between the support layer 11 and the buried oxide layer 13, this phenomenon usually being caused by free electrons that accumulate at the interface under the effect of the fixed positive charges contained in the buried oxide layer 13. Thanks to the trap-rich layer 12, the electrons are trapped and can no longer circulate. The effective resistivity of the support layer 11 is thus increased with respect to a multilayer structure devoid of a trap-rich layer (structure called “HR-SOI”). The trap-rich layer 12 can be constituted of polycrystalline silicon. The traps are located at the grain boundary of the polycrystalline silicon.

The TR-SOI structure 10 greatly improves the RF performance of the integrated circuits manufactured from this structure, in particular in terms of linearity and cross talk. The passive elements (inductances, capacitances . . . ) formed above the active layer 14 benefit from a better quality factor.

FIG. 2 shows as a schematic cross-section view another multilayer structure 20 adapted for radiofrequency applications and described in document WO2017/212160A1.

This multilayer structure 20 successively comprises a support substrate 21 made of high resistivity silicon, a dielectric layer 22 made of silicon dioxide disposed on the support substrate 21, an active layer 23 made of monocrystalline silicon disposed on the dielectric layer 22 and trenches 24 extending in the support substrate 21 from the interface between the support substrate 21 and the dielectric layer 22. The walls of the trenches 24 are lined with a material 25 that has mobile electrical charge trapping properties. The remaining portion of the trenches 24 is filled with a gas or a gaseous mixture, for example air. The trenches are thus conserved at the state of cavities.

Thanks to these cavities, the effective resistivity of the support substrate 21 is further increased.

The manufacturing of the multilayer structure 20 comprises a step of transferring the dielectric layer 22 and the active layer 23 on the support substrate 21. This transfer can be accomplished thanks to a bonding technique (direct or via molecular adhesion) such as the Smart Cut™ method. It remains however complex to implement, because the bonding interface is not entirely constituted of silicon. More particularly, the bonding is made difficult by the presence of the trenches 24.

### SUMMARY

There is therefore a need to provide a method for manufacturing a multilayer structure provided with cavities that is simpler to implement.

According to a first aspect of the invention, this need tends to be satisfied by providing a method for manufacturing comprising the following steps:

providing a stack comprising a substrate and a dielectric layer disposed on the substrate, the substrate being formed from a semiconductor material having a resistivity greater than or equal to 500 Ω.cm,

etching trenches extending through the dielectric layer and opening onto the substrate;

etching the substrate isotropically and selectively with respect to the dielectric layer to form first cavities in the substrate; and

depositing a mobile electrical charge-trapping layer on the walls of the first cavities and on the side walls of the trenches, in such a way as to fill in the trenches in the dielectric layer, thus closing the first cavities in the substrate.

In an embodiment of the method of manufacturing, the stack provided further comprises an active layer disposed on the dielectric layer and a protective layer disposed on the active layer, the etching of the trenches further extending in the active layer and in the protective layer.

According to a development of this embodiment, second cavities are formed in the active layer at the same time as the first cavities in the substrate, by etching of the active layer isotropically and selectively with respect to the dielectric layer and to the protective layer, and wherein the second cavities are filled by the mobile electrical charge-trapping layer.

The method according to the first aspect of the invention can also have one or more of the characteristics hereinbelow, taken individually or according to all technically permissible combinations:

the step of providing the stack comprises a thermal oxidation operation of a surface of the substrate, a nitriding operation of the surface of the substrate or a deposition operation of the dielectric layer on the substrate;

the method further comprises a step of removing a portion of the mobile electrical charge-trapping layer deposited on the dielectric layer;

the trenches further extend in a portion of the substrate;

each trench has a width comprised between 20 nm and 100 nm;

each trench has a length comprised between 50 μm and 2000 μm;

each trench has a depth comprised between 50 nm and 300 nm;

the trenches are of identical dimensions;

the trenches are disjointed and extend in the dielectric layer along planes parallel together and perpendicular to a main face of the substrate;

the trenches are spaced two by two by a distance such that the first cavities merge into one larger cavity during the step of etching of the substrate;

the trenches are spaced two by two by a distance comprised between 300 nm and 5000 nm;

the trenches communicate between them and form a meshing in the dielectric layer;

the trenches have a first pitch comprised between 100 nm and 5000 nm in a first direction and a second pitch comprised between 100 nm and 5000 nm in a second direction secant to the first direction;

each first cavity has a width comprised between 200 nm and 5000 nm;

each first cavity has a length comprised between 50 μm and 2000 μm ; and

each first cavity has a depth comprised between 100 nm and 2500 nm;

the first cavities are of identical dimensions.

A second aspect of the invention relates to a method for manufacturing an integrated circuit, comprising the following steps:

manufacturing a multilayer structure by accomplishing a method according to the first aspect of the invention;

forming passive components on the multilayer structure, vertically with respect to the first cavities.

The method according to the second aspect of the invention can also comprise one or more of the steps hereinbelow, taken individually or according to all technically permissible combinations:

a step of forming electrical insulation trenches before the step of etching the trenches;

a step of forming active components in a first zone of the multilayer structure, the first zone being devoid of first cavities, the passive components being formed in a second zone of the multilayer structure, separate from the first zone and provided with first cavities;

a step of total removal of the dielectric layer before the step of forming active components;

a step of forming at least one level of electrical interconnection that connects the active components, the passive components being formed on the at least one level of electrical interconnection.

A third aspect of the invention relates to a multilayer structure comprising:

a substrate;

a dielectric layer disposed on the substrate;

trenches extending through the dielectric layer to the substrate;

first cavities extending in the substrate, from the interface between the substrate and the dielectric layer;

a mobile electrical charge-trapping layer entirely filling the trenches in the dielectric layer and lining the walls of the first cavities arranged in the substrate.

In an embodiment, the multilayer structure further comprises:

an active layer disposed on the dielectric layer;

second cavities arranged in the active layer and at least partially filled by the mobile electrical charge-trapping layer.

### BRIEF DESCRIPTION OF THE FIGURES

Other characteristics and benefits of the invention shall appear clearly in the description that is given thereof hereinbelow, for the purposes of information and in no way limiting, in reference to the following figures:

FIG. 1, described hereinabove, shows a multilayer structure according to the prior art, that can be used as a starting substrate for the manufacturing of radiofrequency integrated circuits;

FIG. 2, described hereinabove, shows another multilayer structure according to the prior art, also adapted to radiofrequency applications;

FIGS. 3A to 3E show a first embodiment of the method of manufacturing a multilayer structure according to the first aspect of the invention;

FIGS. 4A to 4E show a second embodiment of the method for manufacturing a multilayer structure;

FIG. 5 is a 3D view of the multilayer structure obtained at the end of the method of FIGS. 4A to 4E;

FIGS. 6A to 6D show an alternative embodiment of the method for manufacturing a multilayer structure according to FIGS. 4A to 4E;

FIG. 7 is a 3D view of the multilayer structure obtained at the end of the method of FIGS. 6A to 6D; and

FIG. 8 shows a step of the method for manufacturing an integrated circuit according to the second aspect of the invention.

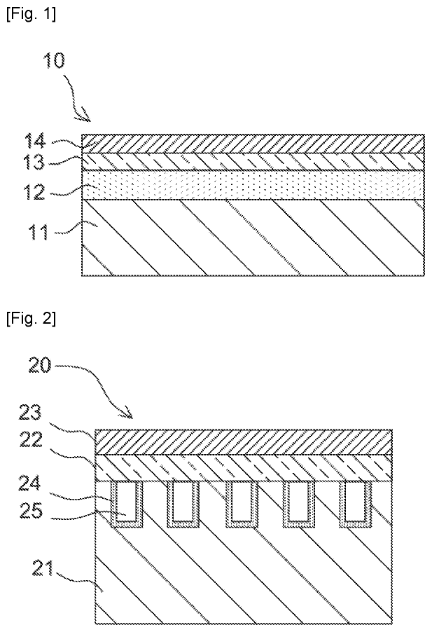

For increased clarity, identical or similar elements are marked with identical reference signs in all the figures.

### DETAILED DESCRIPTION

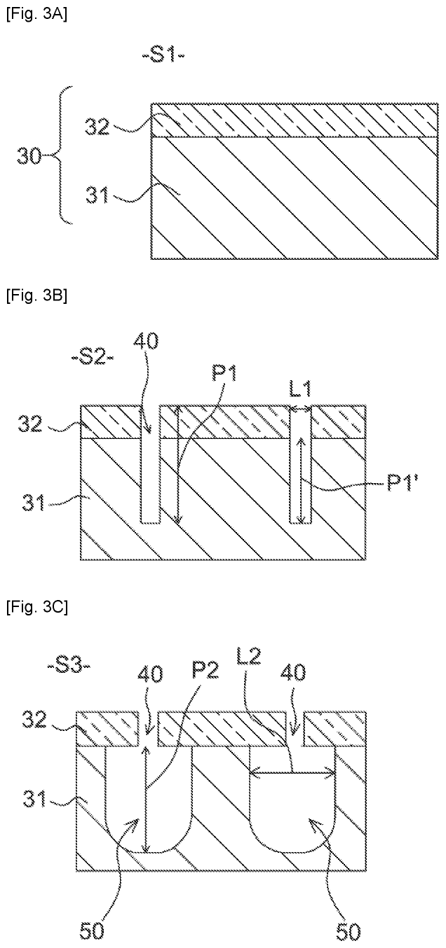

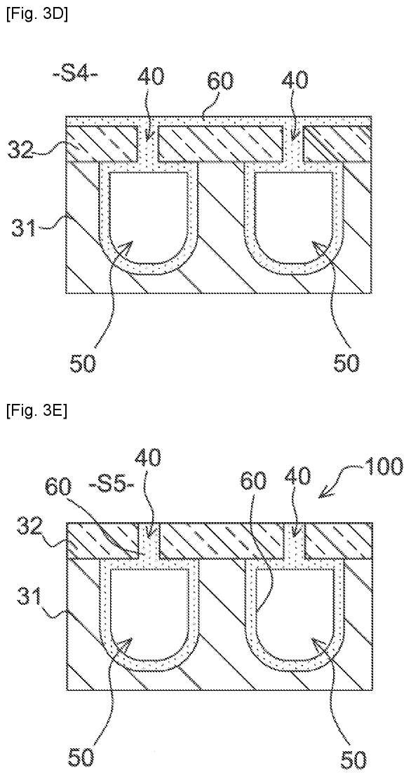

FIGS. 3A to 3E show steps S1 to S5 of a method for manufacturing a multilayer structure 100, according to a first embodiment of the invention.

The step S1 of FIG. 3A consists in providing a stack 30 comprising a substrate 31 and a dielectric layer 32 disposed on the substrate 31.

The substrate 31, also called support layer, is formed from a high resistivity semiconductor material, for example high resistivity silicon. A semiconductor material is here qualified as high resistivity when its electrical resistivity is greater than or equal to 500 Ω.cm. Such a resistivity makes it possible to reduce the leakage currents between the different components (active or passive) formed on the substrate and the eddy currents in the substrate, thus limiting losses by the Joule effect that stem therefrom.

The dielectric layer 32 is formed from a material that can be etched selectively with respect to the material of the substrate 31. The dielectric layer 32 can in particular be constituted of a silicon oxide (for example silicon dioxide, or SiO₂) or of a silicon nitride (e.g. Si₃N₄).

The step S1 of supplying the stack 30 beneficially comprises a thermal oxidation operation (or a nitriding operation) of the surface of the substrate 31 so as to form the dielectric layer 32. A good quality interface can thus be obtained. Alternatively, the step S1 of supplying the stack 30 can comprise a deposition operation of the dielectric layer 32 on the substrate 31, for example by plasma-enhanced chemical vapor deposition (PECVD) or low pressure chemical vapor deposition (LPCVD).

In this first embodiment, the substrate 31 is a so-called “bulk” substrate, i.e. comprised solely of semiconductor material (as opposed to innovative substrates such as the SOI substrate). The thickness of the dielectric layer 32 is in an embodiment comprised between 50 nm and 100 nm.

The dielectric layer 32 can possibly be constituted of a stack of several sublayers, for example a sublayer of silicon oxide surmounted with a sublayer of silicon nitride (STI integration).

In the step S2 of FIG. 3B, trenches 40 are etched through the dielectric layer 32 until reaching the substrate 31. These trenches 40 can be formed thanks to an anisotropic etching technique, such as reactive ionic etching (RIE). Each trench 40 in an embodiment has a width L1 comprised between 20 nm and 100 nm, a length comprised between 50 μm and 2000 μm and a depth P1 comprised between 50 nm and 300 nm. The width L1, also called “critical dimension”, is the smallest dimension of the trenches 40 in a plane parallel to the main face of the substrate 31 (the one on which the dielectric layer 32 is deposited). It is here measured in the cutting plane of FIG. 3B. The length of the trenches 40 is measured perpendicularly to the cutting plane of FIG. 3B. The depth P1 of the trenches 40 is measured perpendicularly to the main face of the substrate 31.

Beneficially, the trenches 40 further extend in a portion of the substrate 31, such as shown in FIG. 3B. The depth P1′ of the trenches 40 within the substrate 31 is in an embodiment comprised between 50 nm and 200 nm.

In the step S3 of FIG. 3C, first cavities 50 are formed in the substrate 31 by etching it isotropically and selectively with respect to the dielectric layer 32. For example, a CF₄/N₂/O₂ plasma can be used to etch (isotropically) a substrate 31 made of silicon selectively with respect to a dielectric layer 32 made of SiO₂.

The first cavities 50 in the substrate 31 communicate with the trenches 40 in the dielectric layer 32. Indeed, the substrate 31 is etched starting from the trenches 40. When the latter emerge on the upper face of the substrate 31, the first cavities 50 globally have the shape of a half cylinder. When the trenches 40 further extend partially in the substrate 31, the first cavities 50 have a more extended shape and extend more deeply in the substrate 31.

In an embodiment, each one of the first cavities 50 has a width L2 comprised between 200 nm and 5000 nm and a depth P2 comprised between 100 nm and 2500 nm. The length of the first cavities 50 is substantially equal to the length of the trenches 40, for example comprised between 50 μm and 2000 μm.

The trenches 40 can have identical dimensions, although that is not necessary to obtain first cavities 50. In the same way, the first cavities 50 can have identical dimensions (such as is the case when the trenches 40 have identical dimensions).

This, in the step S4 of FIG. 3D, a mobile electrical charge-trapping layer 60 is formed on the walls of the first cavities 50 and on the side walls of the trenches 40. A mobile electrical charge-trapping layer designates a layer comprising traps able to capture mobile electrical charges.

The trapping layer 60 beneficially has an electrical resistivity greater than 50 Ω.cm for frequencies comprised between 100 MHz and 100 GHz. Thus, the trapping layer 60 prevents or significantly limits the propagation of electrical signals the frequency of which is comprised between 100 MHz and 100 GHz.

The trapping layer 60 is deposited in such a way as to fill in the trenches 40 in the dielectric layer 32, thus closing the first cavities 50 in the substrate 31. In an embodiment, a conformal deposition technique such as low pressure chemical vapor deposition (LPCVD) is used during the step S4. The trapping layer 60 is then of a constant thickness, for example comprised between 10 nm and 50 nm, and follows the contours of the substrate 31 and of the dielectric layer 32. In particular, the trapping layer 60 covers all the side walls of the trenches 40 and all the walls of the first cavities 50. It also extends to the surface of the dielectric layer 32.

On the other hand, the trapping layer 60 does not entirely fill the first cavities 50. The remaining portion of the first cavities 50 is filled with a gas or gaseous mixture, for example air or other gases introduced into the deposition reactor. The pressure present in the first cavities 50 can be very low (it is in particular according to the partial pressures of the gases introduced into the deposition reactor), so as to reach a practically vacuum configuration. It is in an embodiment comprised between 1 Pa and 100 Pa.

The trapping layer 60 is in an embodiment formed from a material that has properties of trapping mobile electrical charges (electrons), such as polycrystalline silicon.

Alternatively, the trapping layer 60 is made from a dielectric material, for example an oxide such as SiO₂ or a nitride such as SiN.

Finally, the step S5 of FIG. 3E is an optional step consisting in removing the portion of the trapping layer 60 deposited on the dielectric layer 32. This removal can be accomplished by etching, for example by using a plasma, or by chemical mechanical polishing (CMP).

Thus, in reference to FIG. 3E, the multilayer structure 100 comprises:

the substrate 31;

the dielectric layer 32 disposed on the substrate 31;

the trenches 40 extending through the dielectric layer 32 to the substrate 31;

the first cavities 50 extending in the substrate 31, from the interface between the substrate 31 and the dielectric layer 32;

the trapping layer 60 entirely filling the trenches 40 in the dielectric layer 32 and lining the walls of the first cavities 50 arranged in the substrate 31 (without however filling them entirely).

As is known in the field of SOI multilayer structures for radiofrequency applications, a dielectric layer (for example made of SiO₂) on a semiconductor substrate comprises positive charges. These charges are compensated by negative charges coming from the substrate, at the interface with the dielectric layer. These charges generate a parasitic surface conduction (PSC) layer in the substrate under the dielectric layer, which decreases the effective resistivity of the substrate. The electrical performance sensitive to the resistivity of the substrate (such as the linearity of the signal, the level of insertion losses, the quality factors of the passive components . . . ) are therefore substantially degraded by the presence of this conduction layer.

The first cavities 50 and the trapping layer 60 (when the latter is not made from a dielectric material) limit the surface on which the mobile electrical charges accumulate. Furthermore, they prevent the movement of these electrical charges in the substrate 31 at the interface with the dielectric layer 32. The electrical charges are obliged to circumvent the first cavities 50, thus passing through zones of the substrate 31 of higher resistivity (the deeper the first cavities 50 are, the more pronounced this circumventing effect is). This results in that the effective resistivity of the substrate 31 is greatly improved.

The plugs formed by the trapping layer 60 through the dielectric layer 32 and the presence of the trapping layer 60 on the ceiling of the first cavities 50 are recognisable elements of the method of manufacturing a multilayer structure according to the invention.

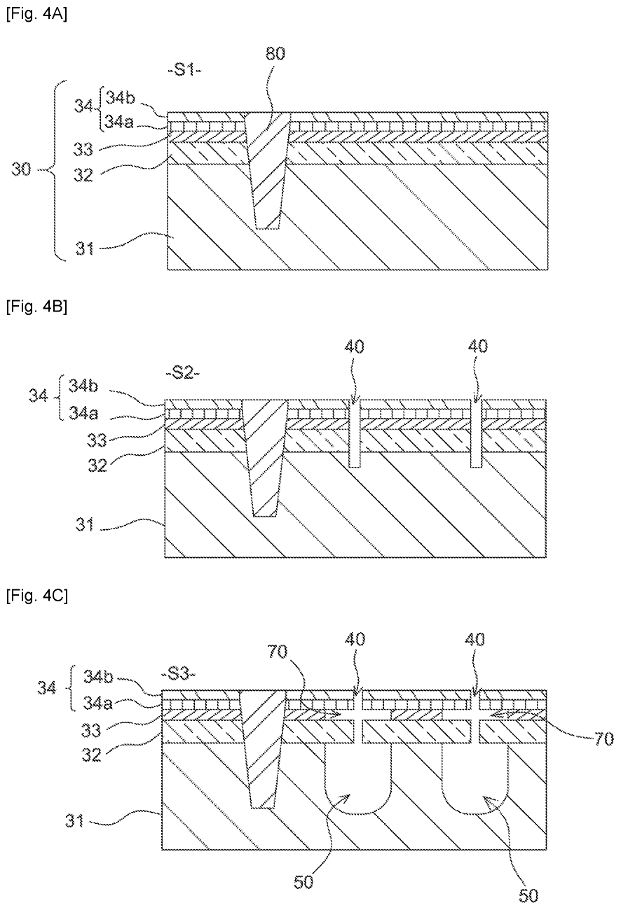

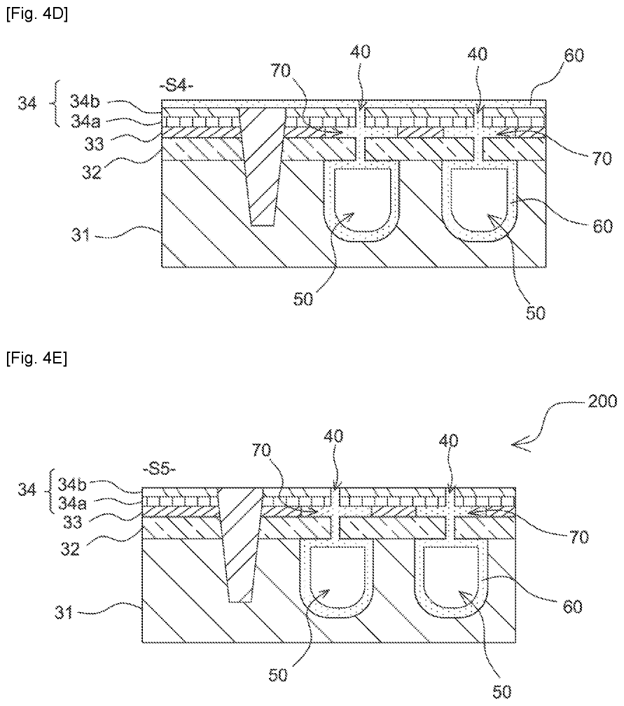

FIGS. 4A to 4E show a second embodiment of the method for manufacturing a multilayer structure. This second embodiment differs from the first embodiment (FIGS. 3A-3E) mainly in the type of substrate used as a starting point for the method for manufacturing: a SOI-type substrate rather than a bulk substrate.

Thus, the stack 30 provided in the step S1 of FIG. 4A comprises, in addition to the substrate (or support layer) 31 made of high resistivity semiconductor material and the dielectric layer 32, an active layer 33 disposed on the dielectric layer 32 and a protective layer 34 disposed on the active layer 33.

The active layer 33 is in an embodiment a thin film of semiconductor material, intrinsic or doped, for example made of monocrystalline silicon, of germanium, of a silicon-germanium alloy or of a III-V semiconductor material. The active layer 33 is more particularly intended for the manufacturing of active components, typically transistors. Its thickness is in an embodiment comprised between 6 nm and 200 nm.

The protective layer 34 has for purpose to protect the active layer 33 during later steps of the method for manufacturing the multilayer structure. It can also be used as a hard mask layer and/or etch stop layer during a method for manufacturing an integrated circuit from the multilayer structure. The protective layer 34 can comprise several superimposed sublayers, for example a first sublayer 34a made of SiO₂ and a second sublayer 34b made of SiN disposed on the first sublayer 34a.

The dielectric layer 32 constitutes the electrically insulating layer of the SOI substrate (also called buried oxide layer or BOX, in the case of an oxide such as SiO₂). In this second embodiment, the thickness of the dielectric layer 32 is beneficially comprised between 20 nm and 400 nm.

After the step S2 of etching trenches 40 shown in FIG. 4B, the trenches 40 extend through the active layer 33 and the protective layer 34 (in addition to the dielectric layer 32 and, possibly, a portion of the substrate 31).

FIG. 4C shows the step S3 of etching the substrate 31, allowing for the formation of first cavities 50. When the material of the substrate 31 and the material of the active layer 33 are of the same nature (for example silicon), or more generally when they are both sensitive to the chemical etching used in the step S3, the active layer 33 is further etched and second cavities 70 are formed in the active layer 33 at the same time as the first cavities 50 in the substrate 31. The etching is isotropic and selective with respect to the dielectric layer 32 and to the protective layer 34.

FIG. 4D shows the step S4 of depositing the trapping layer 60. In addition to entirely filling the trenches 40 and covering the walls of the first cavities 50, the trapping layer 60 fills the second cavities 70 in the active layer 33. The second cavities 70 are in an embodiment entirely filled by the trapping layer 60.

Finally, the upper portion of the trapping layer 60 (deposited on the protective layer 34) is removed in the step S5 shown in FIG. 4E. All or a portion of the protective layer 34 can also be removed during this step S5. For example, the second sublayer 34b made of SiN can be removed (by selective etching or CMP).

The multilayer structure 200 obtained at the end of the method for manufacturing according to the second embodiment (FIG. 4E) comprises, in addition to the elements of the electronic structure 100 (FIG. 3E), the active layer 33, the second cavities 70 partially or entirely filled of the trapping layer 60, and possibly the protective layer 34.

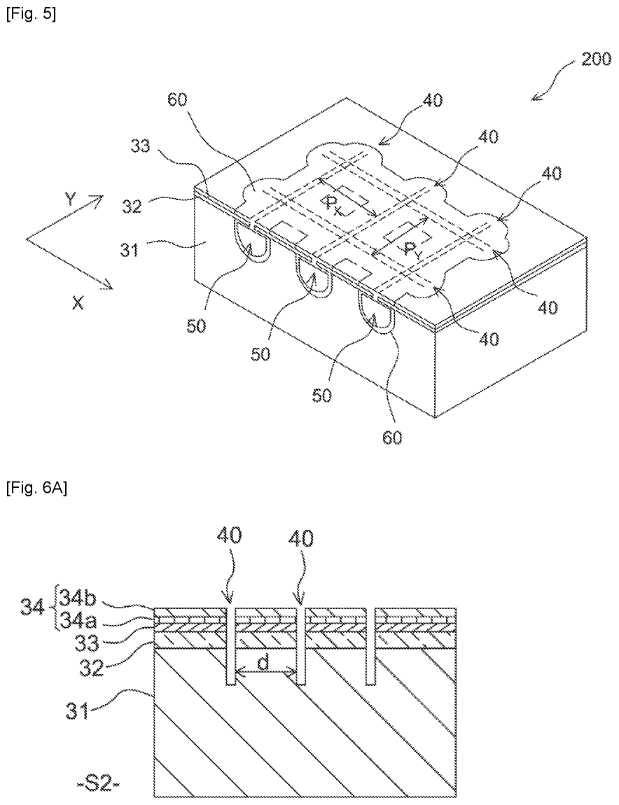

FIG. 5 is a 3D view of the multilayer structure 200 after having entirely removed the protective layer 34. This figure shows that the first cavities 50 can form a network of galleries that communicate between them. More particularly, a first part of the first cavities 50 can extend in a first direction X and a second part of the first cavities 50 can extend in a second direction Y secant (i.e. not parallel) to the first direction X.

Such a multilayer structure 200 is obtained by etching in the step S2 of the trenches 40 that communicate together and form a meshing in the dielectric layer 32. In an embodiment, the trenches 40 have a first pitch (also called spatial period) P_{X} comprised between 100 nm and 5 μmin the first direction X and a second pitch P_{Y} comprised between 100 nm and 5 μmin the second direction Y. By way of example, the trenches 40 form a rectangular meshing (second direction Y perpendicular to the first direction X). The first pitch P_{X} can be equal to the second pitch P_{Y} (square meshing).

In an alternative embodiment not shown in the figures, the trenches 40 are disjointed and all extend along planes parallel to one another and perpendicular to the main face of the substrate 31. They can further have a pitch Px in the first direction X, in an embodiment comprised between 50 nm and 5 μm. The first cavities 50 then all extend parallelly to one another in the second direction Y.

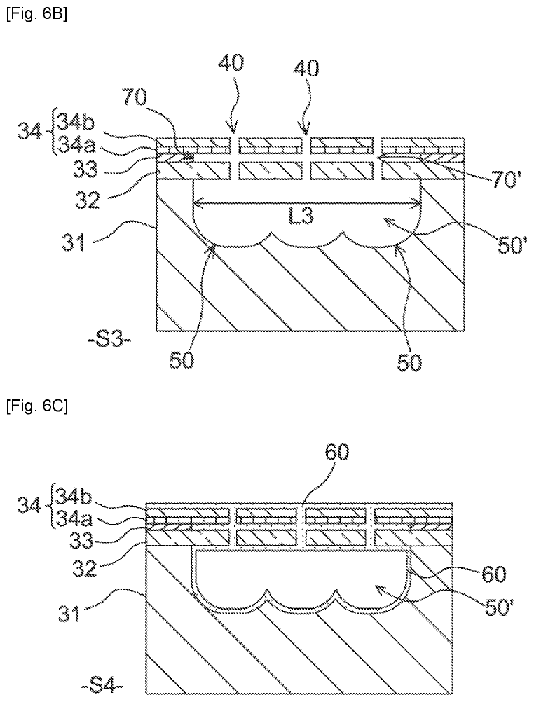

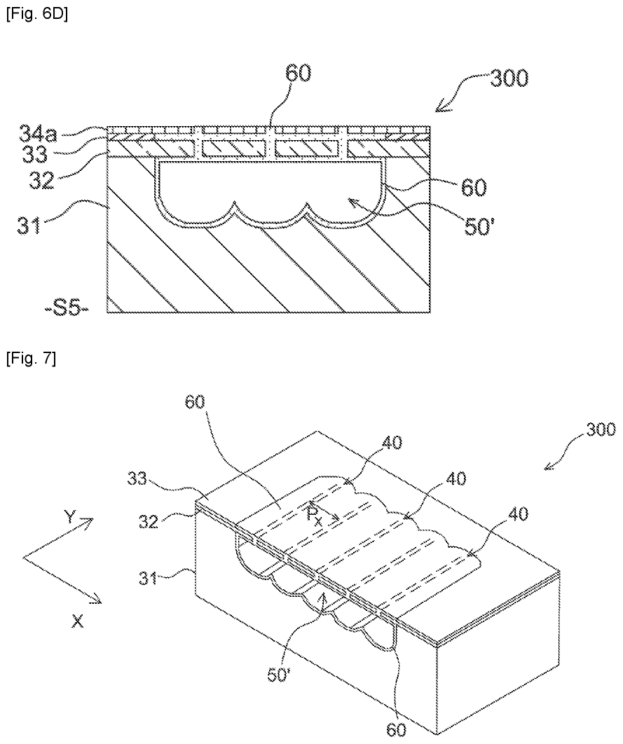

FIGS. 6A to 6D show the steps S2 to S5 according to an alternative embodiment of the method for manufacturing a multilayer structure. This alternative is applicable to the case of a bulk substrate and in the case of a SOI substrate.

In this alternative embodiment, the trenches 40 extend parallelly to one another (for example in the second direction Y). Furthermore, the distance d between two consecutive trenches 40 (measured in the first direction X; cf. FIG. 6A) and the conditions of the isotropic and selective etching (chemistry, duration . . . ) of the step S3 (FIG. 6B) are chosen in such a way that the first cavities 50 merge into one first large cavity 50′. The ceiling of this first large cavity 50′, constituted by portions of the dielectric layer 32, is held by the ends (located in planes parallel to the cutting plane of FIG. 6B). In the case of an SOI substrate, the second cavities 70 also merge into a second large cavity 70′. The steps S4 and S5 of the method for manufacturing (cf.

FIG. 6C and FIG. 6D) are then accomplished in the way described in relation with FIG. 3D-3E or 4D-4E.

FIG. 6D shows a cross-section view of the multilayer structure 300 obtained at the end of this alternative embodiment (with the first protective sublayer 34a).

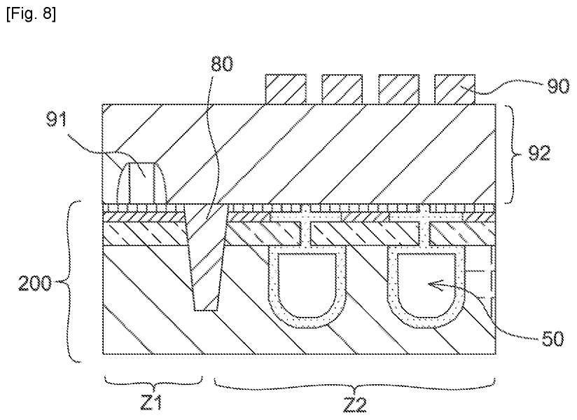

FIG. 7 shows the same multilayer structure 300 in 3D (but without the first protective sublayer 34a). Beneficially, the trenches 40 have a pitch P_{X} in the first direction X, for example comprised between 300 nm and 5 μm.

Thus, thanks to a more substantial spacing of the trenches 40 (and therefore a more substantial spatial period), a wider cavity can be obtained in the substrate 31. The distance d between two consecutive trenches 40 is beneficially comprised between 300 nm and 5000 nm. This distance d can vary from one pair of trenches 40 to the other. In other words, it is not necessary that the trenches 40 be regularly spaced (or that they have identical dimensions) in order to obtain the first large cavity 50′.

In an embodiment, the first large cavity 50′ has a width L3 comprised between 5 μm and 20 μm. Its length and its depth can be respectively identical to the length and the depth P2 of the first cavities 50 when they are disjointed (respectively between 50 μm and 2000 μm and between 100 nm and 2500 nm).

By providing several groups of trenches 40 (regularly spaced or not), it is possible to obtain in the substrate 31 several first large separate cavities 50′ (i.e. non-communicating).

The method for manufacturing a multilayer structure described hereinabove in relation with FIGS. 3A-3E, 4A-4E and 6A-6D is simple to implement and easy to reproduce, as it makes use only of controlled techniques in the microelectronics industry (photolithography, deposition, etching and CMP). It does not contain any step of transfer or bonding, which can be complicated if the surface is structured. It further makes it possible to carry out varied configurations of a multilayer structure provided with cavities (these configurations being independent of the electronic components that can be formed later on the multilayer structure).

Moreover, it can easily be integrated into a method for manufacturing an integrated circuit, for example of the radiofrequency type. The steps S2 to S5 can in particular be accomplished immediately after having formed electrical insulating trenches 80 called STI (for “Shallow Trench Isolation”) in the SOI substrate (cf. FIG. 4A) or the bulk substrate (covered with the dielectric layer 32). The hard mask layer that was used to form the STI 80 can be conserved to form all or a portion of the protective layer 34 of the second embodiment (and more particularly the second sublayer 34b made of SiN).

FIG. 8 shows a step of the method for manufacturing an integrated circuit. After forming the multilayer structure 100, 200 or 300, the method for manufacturing an integrated circuit 400 comprises a step of forming passive components 90 on the multilayer structure. Before the step of forming passive components 90, the method for manufacturing the integrated circuit 400 can also comprise a step of forming active components 91 on the multilayer structure and a step of forming one or more levels of electrical interconnection 92 that connects the active components 91.

The active components 91 are for example transistors. They are for example formed in the active layer 33 of the SOI substrate or on the surface of the bulk substrate 31, in other words in the so-called FEOL (“front-end of line”) portion of the integrated circuit 400. In the case of a bulk substrate, the dielectric layer 32 is entirely removed before forming the active components 91 on the surface of the substrate.

The passive components 90 are for example coils, capacitors, resistors, etc. They are located vertically with respect to the first cavities 50 in the substrate 31 in order to optimise their electrical performance. They are for example formed above the levels of electrical interconnection 92 (or metal levels). Like the levels of electrical interconnection 92, the passive components 90 belong to the so-called BEOL (“back-end of line”) portion of the integrated circuit 400.

The active components 91 can be formed in a first zone Z1 of the multilayer structure, while the passive components 90 are formed in a second zone Z2. The second zone Z2 is separate from the first zone Z1 and provided with first cavities 50. The first and second zones Z1-Z2 are in an embodiment separated by an electrical insulation trench 80.

1. A method for manufacturing an integrated circuit, comprising:
manufacturing a multilayer structure by:
providing a stack comprising a substrate and a dielectric layer disposed on the substrate, the substrate being formed from a semiconductor material having a resistivity greater than or equal to 500 Ω.cm;
etching trenches extending through the dielectric layer and opening onto the substrate;
etching the substrate isotropically and selectively with respect to the dielectric layer to form first cavities in the substrate; and
depositing a mobile electrical charge-trapping layer on walls of the first cavities and on side walls of the trenches so as to fill in the trenches in the dielectric layer, thus closing the first cavities in the substrate, and
forming passive components on the multilayer structure, vertically with respect to the first cavities.

2. The method according to claim 1, further comprising removing a portion of the mobile electrical charge-trapping layer deposited on the dielectric layer.

3. The method according to claim 1, wherein the stack provided comprises an active layer disposed on the dielectric layer and a protective layer disposed on the active layer, the etching of the trenches further extending in the active layer and in the protective layer.

4. The method according to claim 3, wherein second cavities are formed in the active layer at the same time as the first cavities in the substrate, by etching of the active layer isotropically and selectively with respect to the dielectric layer and to the protective layer, and wherein the second cavities are filled by the mobile electrical charge-trapping layer.

5. The method according to claim 1, wherein the trenches are disjointed and extend in the dielectric layer along planes parallel together and perpendicular to a main face of the substrate.

6. The method according to claim 5, wherein the trenches are spaced two by two by a distance such that the first cavities merge into one larger cavity during the etching of the substrate.

7. The method according to claim 1, wherein the trenches communicate between them and form a meshing in the dielectric layer.

8. The method according to claim 7, wherein the trenches have a first pitch comprised between 100 nm and 5000 nm in a first direction and a second pitch comprised between 100 nm and 5000 nm in a second direction secant to the first direction.

9. The method according to claim 1, further comprising forming electrical insulation trenches before the etching of the trenches.

10. The method according to claim 1, further comprising forming active components in a first zone of the multilayer structure, the first zone being devoid of first cavities, the passive components being formed in a second zone of the multilayer structure, separate from the first zone and provided with first cavities.

11. The method according to claim 10, further comprising forming at least one level of electrical interconnection that connects the active components, the passive components being formed on said at least one level of electrical interconnection.

12. An Integrated circuit comprising:
a multilayer structure comprising:
a substrate formed from a semiconductor material having a resistivity greater than or equal to 500 Ω.cm;
a dielectric layer disposed on the substrate;
trenches extending through the dielectric layer to the substrate;
first cavities extending in the substrate, from the interface between the substrate and the dielectric layer; and
a mobile electrical charge-trapping layer lining walls of the first cavities arranged in the substrate and entirely filling the trenches in the dielectric layer, thus closing the first cavities in the substrate;
passive components disposed on the multilayer structure, vertically with respect to the first cavities.

13. The integrated circuit according to claim 12, wherein the multilayer structure further comprises:
an active layer disposed on the dielectric layer;
second cavities arranged in the active layer and at least partially filled by the mobile electrical charge-trapping layer.
